(19) United States
(12) Patent Application Publication
(10) Pub. No.: US 2005/0132961 A1
(43) Pub. Date: Jun. 23, 2005

(54) Catalytic CVD equipment, method for catalytic CVD, and method for manufacturing semiconductor device

(75) Inventor: Tsuyoshi Saito, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies, Inc., Tsukuba-shi (JP)

(21) Appl. No.: 11/012,243

(22) Filed: Dec. 16, 2004

(30) Foreign Application Priority Data
Dec. 19, 2003 (JP) 2003-423265

(51) Int. Cl. C23C 16/00

(52) U.S. Cl. 118/722; 438/778

(57) ABSTRACT

A catalytic CVD equipment comprises: a vacuum chamber; a stage; a first catalyzer; and a second catalyzer. The stage holds a substrate in the vacuum chamber. The first catalyzer is provided in the vacuum chamber and has a bar member arranged substantially in parallel to a major surface of the substrate. The second catalyzer is provided in the vacuum chamber, and has a bar member arranged at a tilted angle to the major surface of the substrate. A thin film is deposited on the substrate held on the stage by introducing a source gas, by heating the first and the second catalyzer, and by decomposing the gas in the vacuum chamber under a low pressure.

### CROSS-REFERENCE TO RELATED APPLICATIONS

This application is based upon and claims the benefit of priority from the prior Japanese Patent Application No. 2003-423265, filed on Dec. 19, 2003; the entire contents of which are incorporated herein by reference.

### BACKGROUND OF THE INVENTION

The present invention relates to a catalytic CVD (Chemical Vapor Deposition) equipment, a method for a catalytic CVD, and a method for manufacturing a semiconductor device, and more specifically, to a catalytic CVD (Chemical Vapor Deposition) equipment and a method for a catalytic CVD, and a method for manufacturing a semiconductor device for forming various thin films on a substrate by reacting source gasses with a catalyzer heated up to high temperature in a vacuum chamber.

Recently, the catalytic chemical vapor deposition (Cat-CVD) method has been developed as a new means for forming thin films using decomposed source gases, as disclosed in Japanese Patent Laid-Open Publication No.2003-073833. In the catalytic CVD method, source gasses are contacted in a reduced pressure atmosphere with a metal filament heated, for example, above 1600° C., and thus subjected to decomposition and/or activation by catalysis to deposit a thin film on a substrate. It becomes possible to reduce thermal and electric damages to the substrate in the catalytic CVD method, since the source gases are decomposed at relatively low temperature without a plasma discharge. Therefore, the applied researches of the catalytic CVD equipment are actively performed as a manufacturing equipment for a high performance semiconductor device, a liquid crystal display and so on. Moreover, the catalytic CVD equipment can be provided cheaply since it does not need the expensive power supply for electric discharge.

In conventional plasma enhanced CVD method, a reaction efficiency of the source gases are only about several percent. On the contrary, in the catalytic CVD method, the reaction efficiency can be attained to almost 80 percent. Furthermore, in the catalytic CVD method, the high quality thin film can be deposited with a high deposition rate and small content of hydrogen.

The catalytic CVD method has another advantage that it can also be applied to a large substrate because a thin film is formed due to a radiating diffusion of active depositing species radiated into all directions from the catalyzer in the catalytic CVD method. Specifically, it is possible to easily minimize a variation of deposition rate on a surface of the large substrate by placing a bar member catalyzer in parallel to a major surface of the substrate in the catalytic CVD method as disclosed by Japanese Patent Laid-Open Publication No.2003-073833.

However, the catalytic CVD method is needed to be improved in coverage at a step or a trench. If the thin film, such as silicon, is deposited by the catalytic CVD method, the deposition rates on a side surface of a step and inside surface of a trench provided on the substrate are low. It is considered that this is related to a deposition mechanism of the catalytic CVD method. As mentioned above, in the catalytic CVD method, a formation direction is determined by radiating diffusion of active depositing species from the catalyzers. In the plasma enhanced CVD method using the source gases decomposed by discharged plasma and in a sputtering film formation method, since charged particles exist as depositing species, the particles can be provided with directions by an electric field or a magnetic field. Therefore, a bottom portion of the high step can be deposited sufficiently on the substrate.

On the contrary, it is difficult to uniform or control the direction of depositing particles since the charged particles do not exist inherently in the catalytic CVD method. The density of the depositing species spread from the catalyzer is inversely proportional to the square of a distance from the catalyzer, since a thin film forming is determined by radiating diffusion from the catalyzer in the catalytic CVD method as mentioned above. For this reason, there is a problem that the step coverage of the thin film deposited on the substrate becomes poor since a so-called “shadow effect” prevents a thin film from growing on the side surface and at the bottom surface of the step.

### SUMMARY OF THE INVENTION

According to an embodiment of the invention, there is provided a catalytic CVD equipment comprising: a vacuum chamber maintainable a low pressure; a stage for holding a substrate in the vacuum chamber; a first catalyzer of bar member provided in approximately parallel to the major surface of the substrate; and a second catalyzer of bar member provided at a tilted angle to the major surface of the substrate; wherein a thin film is deposited on the substrate held on the stage by a process which includes a step introducing at least a source gas, a step heating the first and the second catalyzer, and a step decomposing at least the gas in the vacuum chamber under the low pressure.

According to other embodiment of the invention, there is provided a catalytic CVD method comprising: heating a catalyzer; generating species by decomposing at least a gas through a reaction with the catalyzer; and depositing the species on a substrate, wherein at least a part of the catalyzer is provided at a tilted angle to a major surface of the substrate.

According to other embodiment of the invention, there is provided a method for manufacturing a semiconductor device comprising: forming a first insulating film on a substrate including a semiconductor layer, wherein the forming the first insulating film uses a catalytic CVD method by which a catalyzer is heated, at least a gas is decomposed through a reaction with the catalyzer, depositing species are generated and the species are deposited on the substrate. As a result, a catalytic CVD equipment and a method for catalytic CVD and a method for manufacturing a semiconductor device which have excellent step coverage can be provided.

### BRIEF DESCRIPTION OF THE DRAWINGS

The present invention will be understood more fully from the detailed description given here below and from the accompanying drawings of the embodiments of the invention. However, the drawings are not intended to imply limitation of the invention to a specific embodiment, but are for explanation and understanding only.

In the drawings:

FIG. 1 is a cross-sectional view of the catalytic CVD equipment according to an embodiment of the invention;

FIG. 2 is a plane view of the catalyzers in the catalytic CVD equipment according to an embodiment of the invention;

FIG. 3 is a diagram for explaining an effect of the second catalyzer 13;

FIGS. 4A and 4B show cross-sectional views showing a thin film forming process when the depositing species accumulate on the substrate having the steps from directly above the substrate;

FIGS. 5A and 5B show cross-sectional views showing the thin film forming process by the catalytic CVD equipment of this embodiment;

FIG. 6 is a cross-sectional view showing a structure of the substrate used by the Inventor;

FIGS. 7A and 7B are schematic cross-sectional views showing the process steps for manufacturing the embedded structure;

FIG. 8 is a plane view of the catalyzers 12 and 13 according to the second example;

FIG. 9 is a plane view of the catalyzers 12 and 13 according to the third example;

FIG. 10 is a schematic diagram showing the catalytic CVD equipment in which a plurality of power supplies are provided;

FIG. 11 is a schematic diagram illustrating the catalytic CVD equipment in which the first and the second catalyzers consist of a one-piece bar;

FIG. 12 is a schematic diagram illustrating the catalytic CVD equipment in which the first and the second catalyzers consist of a one-piece bar;

FIG. 13 is a plane view of the catalyzers shown in FIG. 12;

FIG. 14 is a plane view of the catalyzers according to another example;

FIG. 15 is a cross-sectional structure of MOSFET (Metal Oxide Semiconductor Field Effect Transistor);

FIGS. 16A through 16C are process cross-sectional views illustrating the manufacturing method of the gate side wall 105;

FIG. 17 is a schematic view illustrating the cross-sectional structure of a relevant part of another semiconductor device manufactured according to the invention;

FIG. 18A thorough FIG. 18C are process cross-sectional views showing a method of manufacturing a semiconductor device of the specific example shown in FIG. 17;

FIG. 19A thorough FIG. 19C are process cross-sectional views showing a method of manufacturing a semiconductor device of the specific example shown in FIG. 17;

FIG. 20A thorough FIG. 20C are process cross-sectional views showing a method of manufacturing a semiconductor device of the specific example shown in FIG. 17;

FIG. 21A thorough FIG. 21B are process cross-sectional views showing a method of manufacturing a semiconductor device of the specific example shown in FIG. 17; and

FIG. 22A thorough FIG. 22B are process cross-sectional views showing a method of manufacturing a semiconductor device of the specific example shown in FIG. 17.

### DETAILED DESCRIPTION

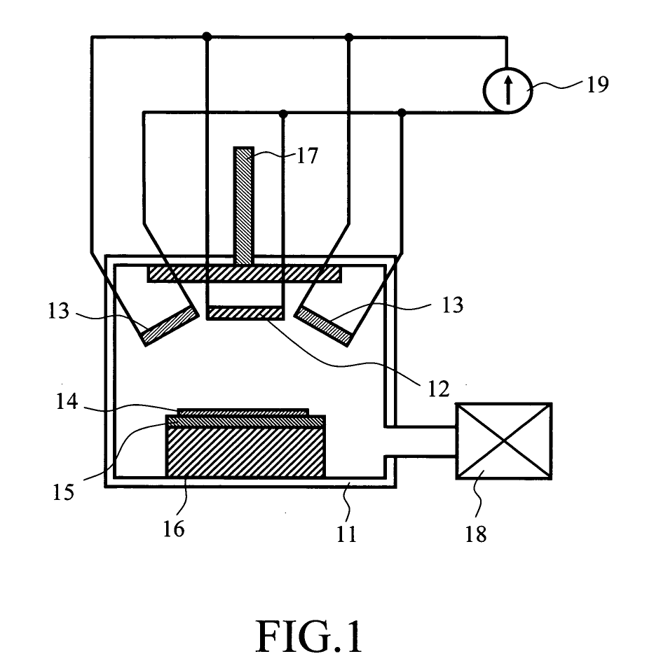

Referring to drawings, some embodiments of the present invention will now be described in detail. FIG. 1 is a schematic diagram illustrating the cross-sectional structure of the catalytic CVD equipment according to an embodiment of the invention.

First catalyzers 12 and second catalyzers 13 are disposed in the vacuum chamber 11. These catalyzers 12 and 13 can be formed of thin metal wire, for example. Moreover, it is a feature that these catalyzers 12 and 13 are arranged at different angles to a substrate. As materials of these catalyzers, tungsten (W), tantalum (Ta), platinum (Pt), palladium (Pd), molybdenum (Mo), titanium (Ti), vanadium (V), silicon (Si), and alumina (AlOx) can be used, for example.

In a lower portion of the vacuum chamber 11, an electrostatic chuck 15 is provided on a heater 16, and a substrate 14 is provided on the electrostatic chuck 15. The substrate 14 is fixed on the substrate stage with the electrostatic chuck 15, and the temperature of the substrate is controlled at a predetermined temperature by the heater 16. If the substrate 14 can be rotated by a rotating means (not shown), the uniformity of the film thickness can be improved further. The source gases are introduced into the vacuum chamber 11 from the external through a gas nozzle provided above the vacuum chamber 11. The pressure in the vacuum chamber 11 is kept at a predetermined pressure appropriately exhausted by vacuum pumping means 18.

In case of deposition, a predetermined pressure is kept by introducing the predetermined source gases through the gas nozzle 17 after exhausting the interior atmosphere of the vacuum chamber 11 to a predetermined degree of vacuum. Subsequently, the first catalyzers 12 and the second catalyzers 13 are heated to a temperature at which a catalytic reaction can occur by supplying the current to these catalyzers from the direct-current supply 19. Then, depositing species are generated as a decomposition product of the source gases due to catalytic reaction of these catalyzers 12 and 13. Subsequently, these depositing species accumulate on the substrate 14. Consequently, a thin film is formed.

Although the circuit in which the currents are supplied to the first catalyzers 12 and the second catalyzers 13 in parallel from one direct-current power supply 19 in FIG. 1, the invention is not limited to this example. For example, the current may be supplied to these catalyzers 12 and 13 in series. Or, a plurality of power supplies may supply the currents to these catalyzers 12 and 13. When a plurality of power supplies are used, there is an advantage that the temperature can be controlled independently in each catalyzer.

In the embodiment of the invention, the first catalyzers 12 are disposed approximately parallel to the major surface of the substrate 14. On the other hand, the second catalyzers 13 are provided at a tilted angle to the major surface of the substrate 14. And, it is desirable to provide the second catalyzers 13 at a position apart from the central position directly above the substrate 14. Even if the steps and the trenches are formed on the surface of the substrate 14, the coverage of the side and the bottom on the substrate 14 can be improved in this structure.

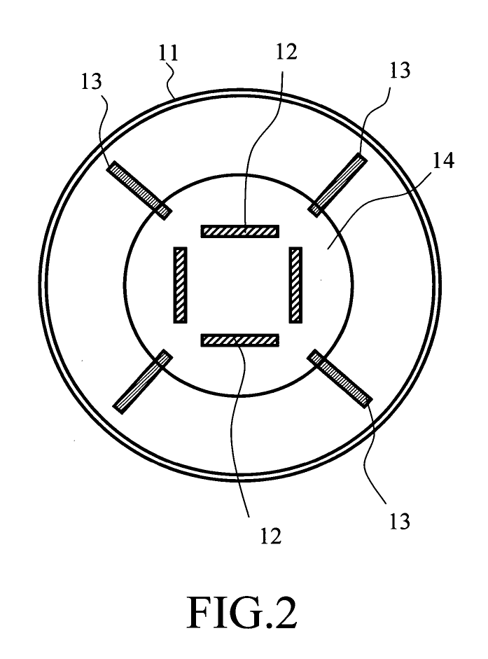

FIG. 2 is a schematic diagram illustrating a plane arrangement of the catalyzers in the catalytic CVD equipment according to the embodiment of the invention. In this embodiment, the four first catalyzers 12 arranged in approximately parallel to the major surface of the substrate 14 are provided in a square fashion surrounding the main axis of the vacuum chamber 11 of a approximately cylinder shape in directly above the substrate 14. On the other hand, four second catalyzers 13 arranged in a tilted angle to the substrate 14 are provided in a radial fashion in the radius direction of the main axis of the vacuum chamber 11 of a approximately cylinder shape apart from the central position directly above the substrate. That is, the second catalyzers 13 are provided apart from the central position directly above the substrate.

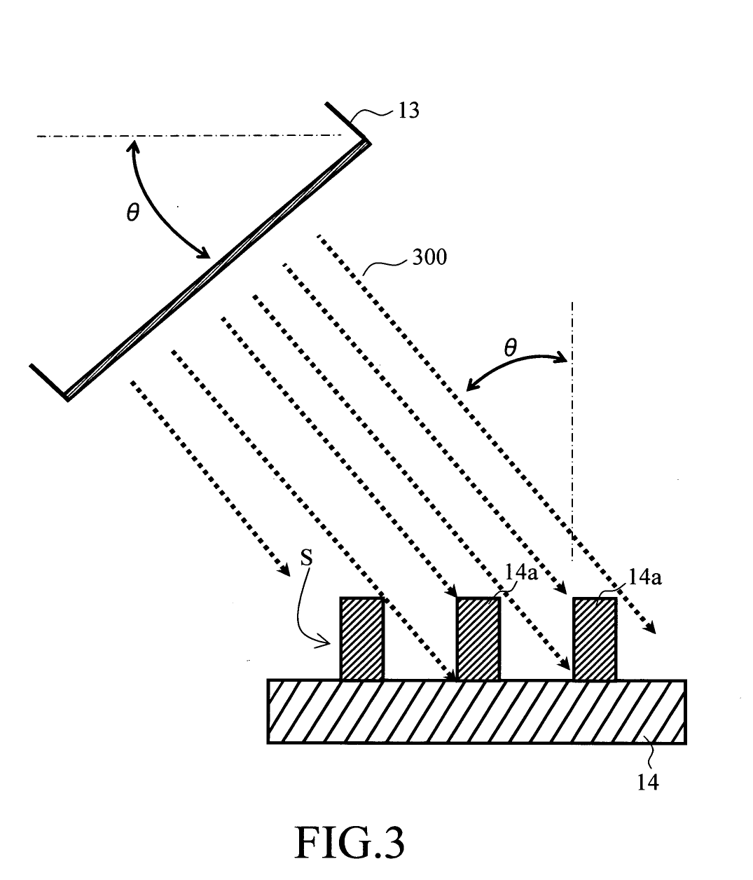

FIG. 3 is a schematic diagram for explaining an effect of the second catalyzers 13. Since the second catalyzers 13 are provided at a tilted angle to the major surface of the substrate 14, the depositting species 300 generated from the second catalyzers 13 tend to accumulate on to the substrate 14 at a tilted angle. When an angle between the second catalyzer 13 and the major surface of the substrate 14 is θ, an angle between depositing direction of the depositing species 300 and a normal line of the substrate 14 approaches θ.

Therefore, when the step 14 a is formed on the substrate 14, the depositing species 300 is fully supplied also to the sides S. Consequently, step coverage is improved.

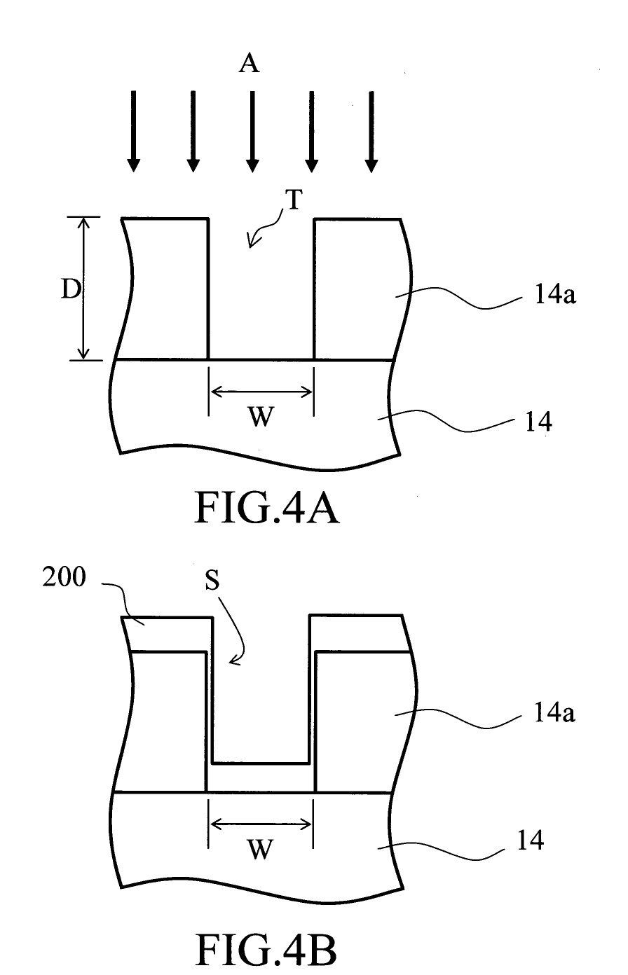

FIGS. 4A and 4 B are schematic cross-sectional views showing a thin film forming process when the depositing species accumulate on the substrate having the steps from directly above the substrate. If the depositing species accumulate on the substrate as shown with an arrow A in FIG. 4A only from directly above the substrate on which the step 14 a including a trench T is formed, the coverage of the sidewalls of the trench becomes poor. Since the deposition rate of the thin film 200 on the sidewall S is low, the thickness becomes relatively small as shown in FIG. 4B. Such poor step coverage is called “stepped cut”. Consequently, the problems such as poor insulation and poor electrical connection arise.

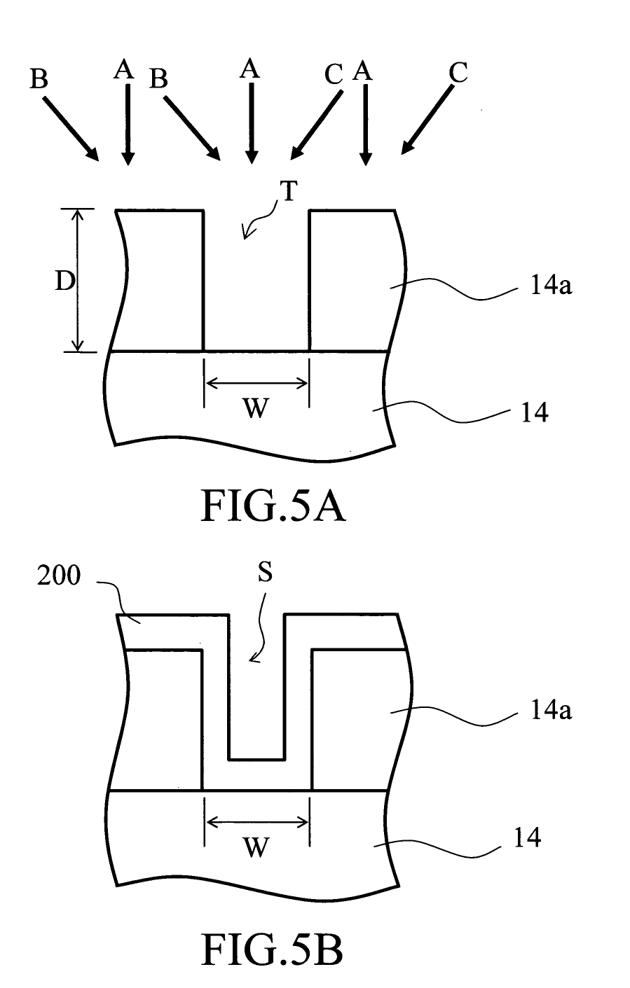

FIGS. 5A and 5 B are schematic cross-sectional views showing the thin film forming process by the catalytic CVD equipment of this embodiment. According to this embodiment, the depositing species accumulating on the substrate 14 at a tilted angle increase by providing the second catalyzers 13. The depositing species accumulating at a tilted angle to the substrate as shown with arrows B and C increase in addition to the depositing species accumulating perpendicularly to the substrate as shown with an arrow A in FIG. 5A. As a result, the deposition rate of the sidewall S of the trench T increases as shown in FIG. 5B. Consequently, step coverage is improved. Therefore, when an insulating film is deposited, for example, the problem such as poor insulation and current leak due to stepped cut can be avoided. When a conducting layer is deposited, for example, a poor electric connection due to stepped cut can be avoided.

The Inventor experimented in deposition of a thin film using the catalytic CVD equipment having a structure expressed in FIGS. 1 and 2. The silicon wafer of 300 mm in diameter was used as the substrate 14. The first catalyzers 12 and the second catalyzers 13 were formed by tungsten (W) wires of 100 mm in length, respectively. And the first catalyzers 12 were provided in parallel to the major surface of the substrate 14 at a position almost directly above the substrate 14 and 200 mm apart from the substrate 14. On the other hand, the second catalyzers 13 were provided at a 30-degree angle to the major surface of the substrate 14 apart from the central position directly above the substrate 14, as shown in FIGS. 1 and 2.

Moreover, a step 14 a having 100 nm width W and 200 nm height D was formed on the surface of the substrate 14.

The substrate temperature was kept at 350 degrees centigrade. The ammonia (NH₃) of 200 sccm and the silane (SiH₄) of 6 sccm were introduced through the gas nozzle 17. The pressure in the vacuum chamber 11 was kept at 30 Pa by the vacuum exhaust equipment 18. The silicon nitride (SiNx) was deposited on the surface of the substrate 14 by supplying currents through the first catalyzers 12 and the second catalyzers 13 from the direct-current power supply 19 and keeping the catalyzers at about 1700 degrees centigrade.

In this experiment, the angles of gradient θ of the second catalyzers 13 were made into 30 degrees corresponding to the step 14a of 100 nm width W and 200 nm height D formed on the surface of the substrate 14. The angle of the accumulating direction of the depositing species from the second catalyzers 13 was 60 degrees to the major surface of the substrate 14. As a result, the sides S of the step 14 a were not covered by the shadow effect. The depositing species accumulate onto all area of the side S. On the other hand, as shown in FIGS. 5A and 5B, since the depositing species accumulated from the approximately directly above the major surface of the substrate 14 in the direction of an arrow A in the bottom of the trench T, the deposition rate was kept.

As a comparative example, the substrate 14 was deposited only from the first catalyzers 12 without supplying a current through the second catalyzers 13.

In the comparative example, as shown in FIGS. 4A and 4B, the coverage of the side S of the trench T is at most 30% of the thickness of the deposit on the plane. However, according to the embodiment of the invention, it turned out that the coverage is improvable to 50% or more.

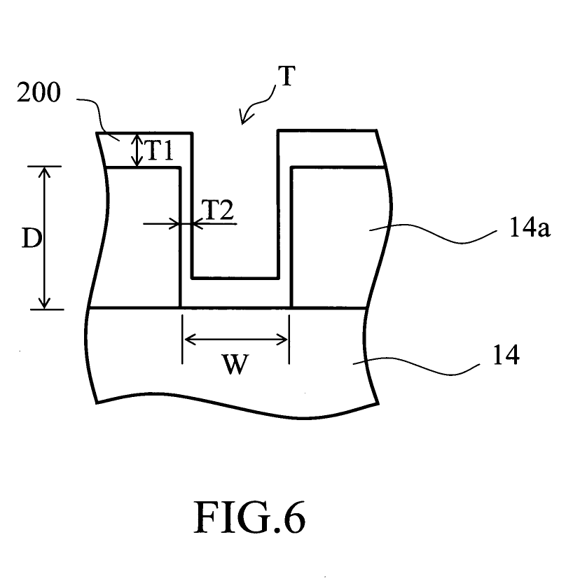

Furthermore, the Inventor performed the deposition experiment, by varying the tilted angles of the second catalyzers 13 (the angle θ in FIG. 3) variously. As a result, the step coverage of the substrate was improved at a range of 30-75 degrees. FIG. 6 is a schematic cross-sectional view showing a structure of the substrate used by the Inventor. The trench T which had a width W of 100 nm and a depth D of 200 nm was formed on the substrate 14. Moreover, the silicon nitride 200 was deposited thereon. And the thickness T1 of the silicon nitride 200 formed on the step 14 a and the thickness T2 of the silicon nitride 200 deposited on the side wall of the trench T were measured, respectively. The coverage was estimated by a ratio between these thickness T1 and T2. Based on this result, the degree of the coverage was defined, as shown in Table 1.

TABLE 1

| T1/T2 | coverage |
|---|---|
| below 30% | X |
| 30%˜50% | Δ |
| above 50% | ◯ |

Table 2 is a table showing the dependence of the step coverage on the tilted angle θ of the catalyzers 13.

TABLE 2

| θ | coverage |
|---|---|
| 15 degrees | Δ |
| 30 degrees | ◯ |
| 40 degrees | ◯ |
| 50 degrees | ◯ |
| 60 degrees | ◯ |
| 70 degrees | ◯ |
| 75 degrees | ◯ |
| 80 degrees | Δ |
| 85 degrees | X |

It was found that the coverage was improved when the tilted angle of the catalyzers 13 was within the range of 15-80 degrees. Moreover, the coverage is further improved at a range of 30-75 degrees of the tilted angle θ of the catalyzers 13. When the tilted angle θ exceeds 75 degrees, the thickness of the rim of the substrate tends to become great, since the distance between the catalyzers 13 and the substrate becomes small. In other words, the film thickness uniformity was degraded within a wafer.

On the other hand, according to this embodiment of the invention, the depositing species accumulating on the substrate at a tilted angle can be further increased by increasing appropriately the number of the second catalyzers 13 provided at a tilted angle to the major surface of the substrate. Consequently, it becomes possible to realize a so-called “embedded structure”.

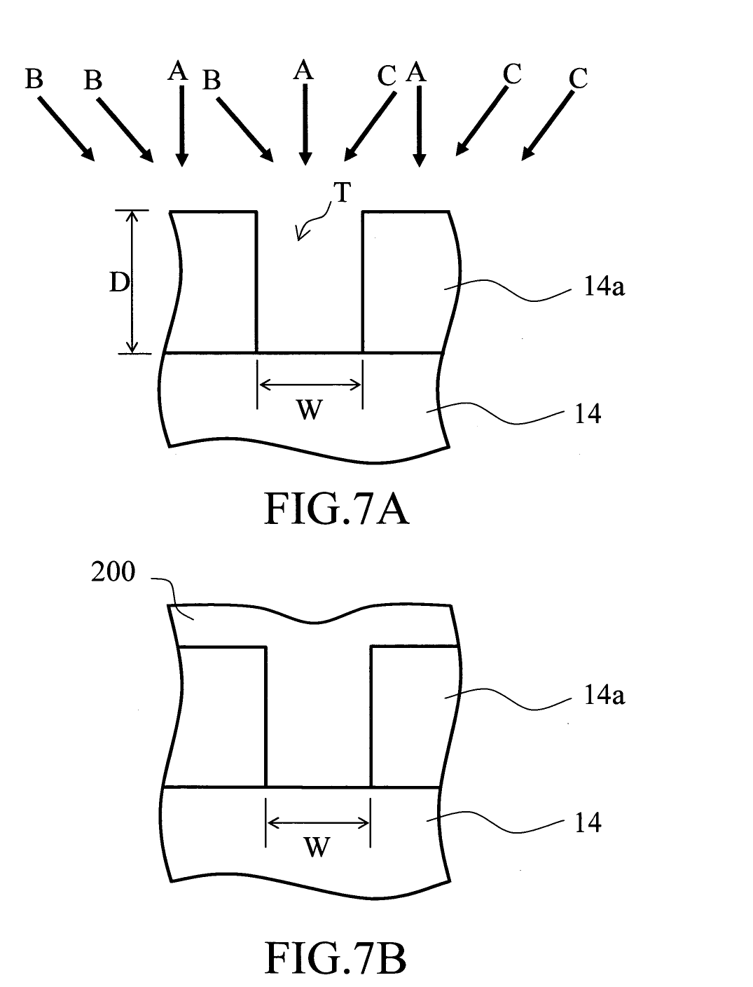

FIGS. 7A and 7B are schematic cross-sectional views showing the process steps for manufacturing the embedded structure. If the rate of the depositing species accumulating on the substrate at a tilted angle increase, the deposition rate on the side S of the trench T increase relatively as shown with arrows B and C in FIG. 7A. Consequently, a flat surface can be formed by filling the trench T with a thin film 200 as shown in FIG. 7B.

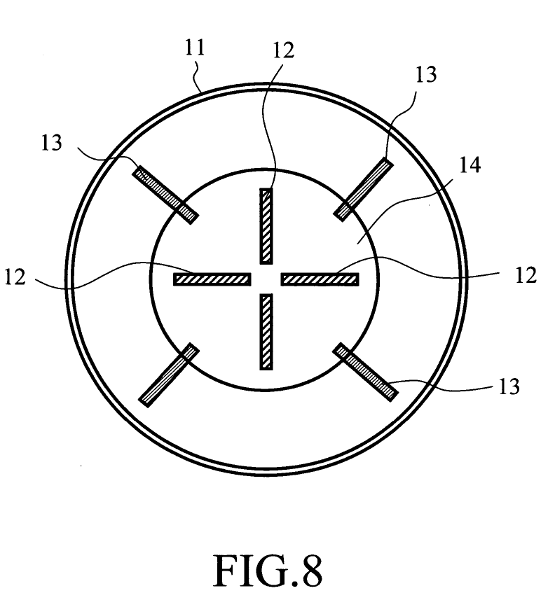

The arrangement relations and number of the first catalyzers 12 and the second catalyzers 13 in the embodiment of the invention can be appropriately determined according to the size and the arrangement relations of the substrate 14, and form and the depth of the step, for example. FIG. 8 is a schematic diagram showing the plane arrangement of the catalyzers 12 and 13 as the second example. The first catalyzers 12 may be arranged in a radial fashion approximately parallel to the major surface of the substrate 14 approximately above the substrate 14.

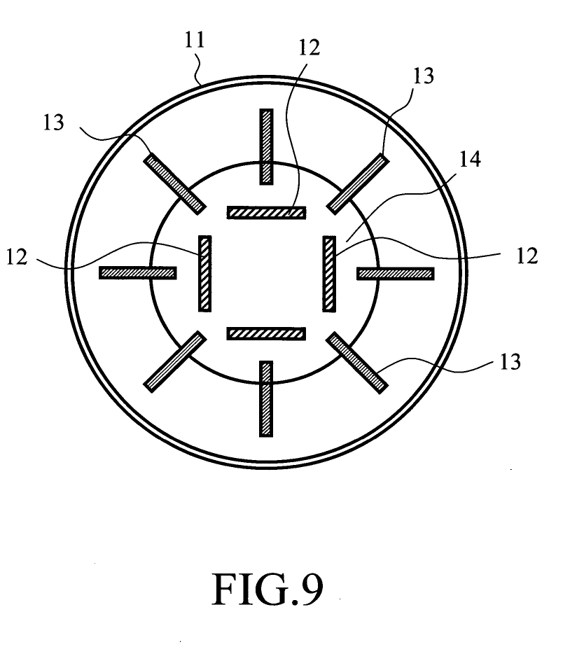

FIG. 9 is a schematic diagram showing the plane arrangement of the catalyzers 12 and 13 as the third example. Thus, the depositing species accumulating on the substrate at a tilted angle can be supplied from the circumference uniformly, by increasing the number of the second catalyzers 13 provided at a tilted angle to the substrate 14. Moreover, the uniformity of the thickness can be improved by depositing rotating the substrate 14 with a rotating means not shown.

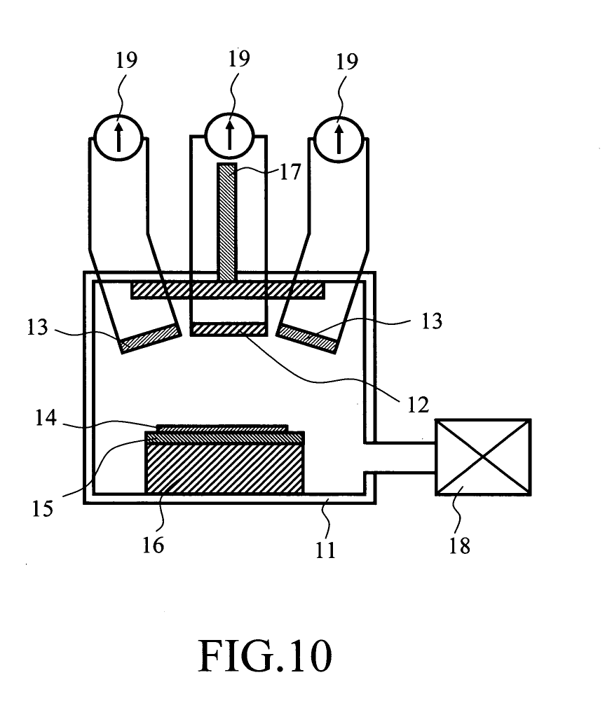

FIG. 10 is a schematic diagram showing the catalytic CVD equipment in which a plurality of power supplies are provided. The current may be supplied to each catalyzer (12 or 13) by each power supply independently. Then, there is an advantage that each temperature of the catalyzer can be controlled independently. That is, it becomes easy to adjust appropriately the balance between the depositing species accumulating on the substrate from directly above the substrate 14 and the depositing species accumulating on the substrate at a tilted angle.

In the embodiment of the invention, it is not necessarily to provide the first catalyzers 12 and the second catalyzers 13 independently. One part of a one-piece bar can be used as the first catalyzers 12 and the other parts of the one-piece bar can be used as the second catalyzers 13.

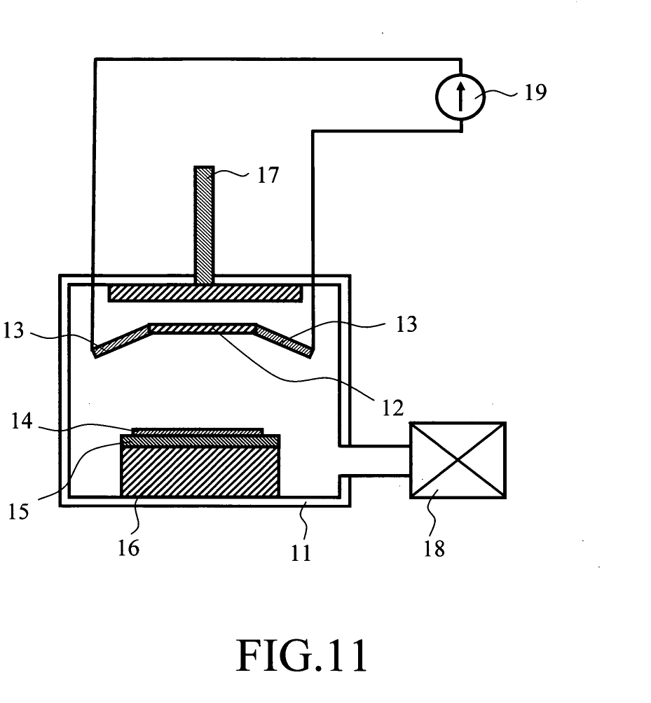

FIG. 11 is a schematic diagram illustrating the catalytic CVD equipment in which the first and the second catalyzers consist of a one-piece bar. Some parts of the bar consisting of such as tungsten (W) as a catalyzer material are provided in approximately parallel to the major surface of the substrate 14, and other parts are provided at a tilted angle to the substrate. Then, one parts of the bar provided in parallel act as the first catalyzers 12, and the other parts provided at a tilted angle act as the second catalyzers 13.

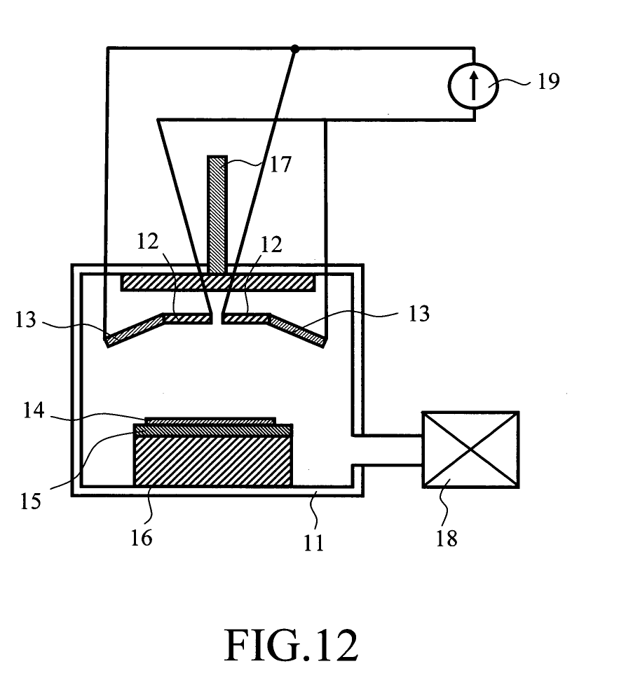

FIG. 12 is a schematic diagram illustrating the catalytic CVD equipment in which the first and the second catalyzers consist of a one-piece bar.

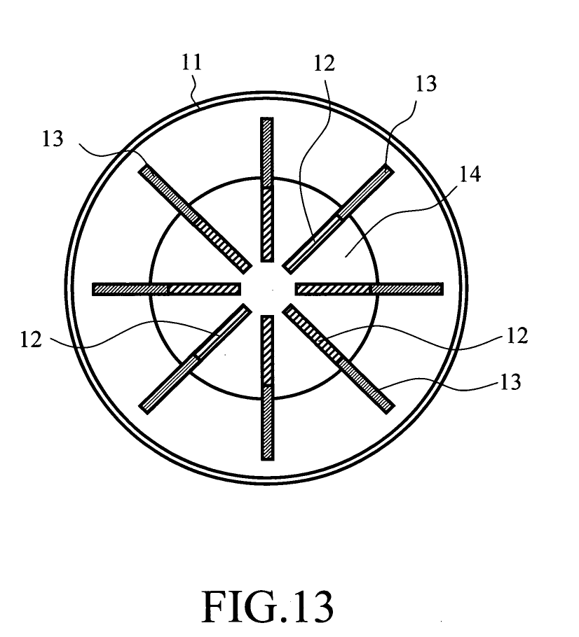

FIG. 13 is a schematic diagram illustrating a plane arrangement of the catalyzers in this example.

In the case of this example, the bars are arranged in a radial fashion around a main axis of the substrate 14. One parts of the bar provided directly above the substrate 14 can act as the first catalyzers 12 by arranging in approximately parallel to the substrate. The other parts of the bar can act as the second catalyzers 13 by arranging at a tilted angle to the major surface of the substrate 14.

It becomes possible to reduce numbers of feed-through for current supply and wiring and to simplify a structure of the equipment by forming the first and the second catalyzers by the one-piece bar.

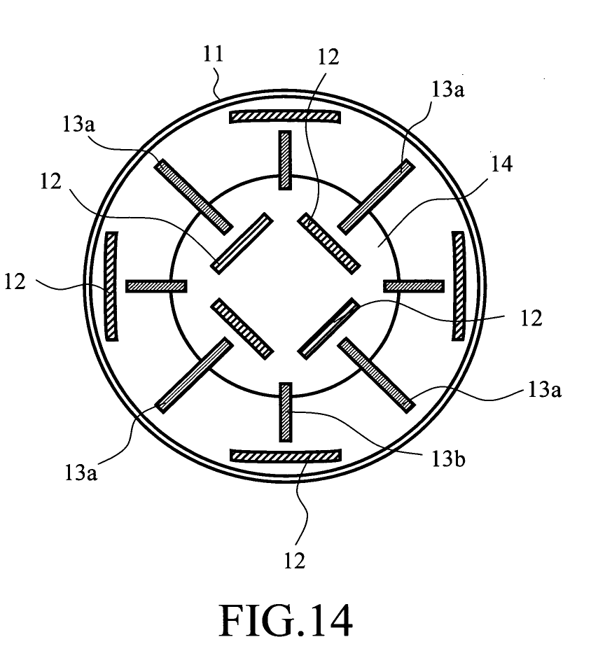

FIG. 14 is a plan view of the catalyzers as another example. Also in this example of the invention, the first catalyzers 12 are disposed approximately in parallel to the major surface of the substrate 14, and the second catalyzers 13 are provided at a tilted angle to the major surface of the substrate 14. The four first catalyzers 12 are arranged above the substrate 14, and other four catalyzers 12 are arranged outside the substrate 14. All of the first catalyzers 12 are arranged approximately in parallel to a tangent to the circumference of the substrate 14.

On the other hand, the second catalyzers 13 are arranged in a radial fashion from a main axis on the substrate 14. The second catalyzers 13 incline downward as distances from the substrate 14 increase, as shown in FIGS. 10 through 12. Moreover, the tilted angles of the long catalyzers 13a and those of the short catalyzers 13b may be same, or may be different from each other in FIG. 14. The Inventor deposited the silicon nitride film on the substrate 14 under a following condition in the arrangement of this example:

Temperature of the first catalyzer 12: 1800 degrees centigrade

Temperature of the second catalyzer 13: 2000 degrees centigrade

Tilted angle θ of the second catalyzer 13: 30 degrees

Pressure: 10 Pascal

Flux of SiH₄: 12 sccm

Flux of NH₃: 300 sccm

Temperature of the substrate 14: 300 degrees centigrade

Consequently, in the trench which has the aspect ratio (D/W) of 2, the coverage (T1/T2) can be improved to 60% or more.

As explained above, according to the embodiment of the invention, it becomes possible to improve the step coverage markedly by increasing the depositing species accumulating on the major surface of the substrate at the tilted angle. As the result, various effects can be acquired by applying the embodiment of the invention to manufacture integrated circuits, for example.

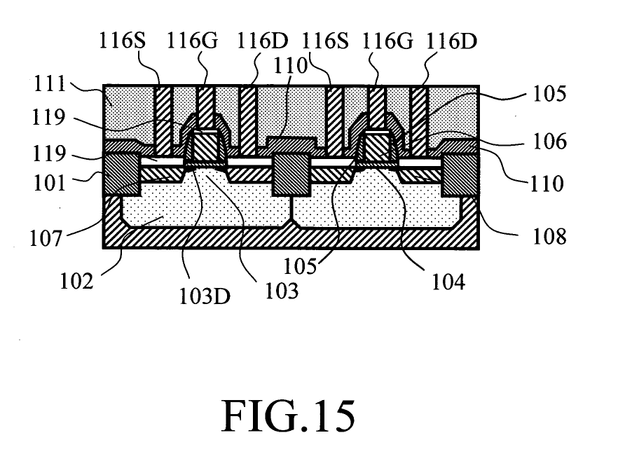

FIG. 15 is a schematic view illustrating a cross-sectional structure of MOSFETs.

More specifically, the surface portion of a silicon substrate is isolated and separated by component separation regions 101, and a MOSFET is formed in each of the separated wells 102. Each MOSFET comprises a source region 107, a drain region 108, and a channel 103 provided between them. A gate electrode 106 is provided on the channel 103 via a gate isolation film 104. LDD (lightly doped drain) regions 103D are provided between the source/drain region 107, 108 and the channel 103 for the purpose of preventing the so-called “short channel effect”. A gate sidewall 105 is provided adjacent to the gate electrode 106 on the LDD region 103D. The gate sidewall 105 is provided in order to form the LDD region 103D in a self-aligned manner.

Silicide layers 119 are provided on the source/drain region 107, 108 and the gate electrode 106 for improving contact with the electrodes. The upper side of this structure is covered with a silicon nitride film 110 and an interlayer isolation film 111, through which contact holes penetrate. Source wiring 115S, gate wiring 115G, and drain wiring 115D are formed through the contact holes.

When a transistor of such a semiconductor integrated circuit is manufactured, the gate sidewall 105 is formed from silicon nitride film. However, if the silicon nitride film has poor step coverage, the thickness of silicon nitride film grown as the gate sidewall 105 varies depending on the distance to adjacent patterns, which causes variation of the transistor threshold.

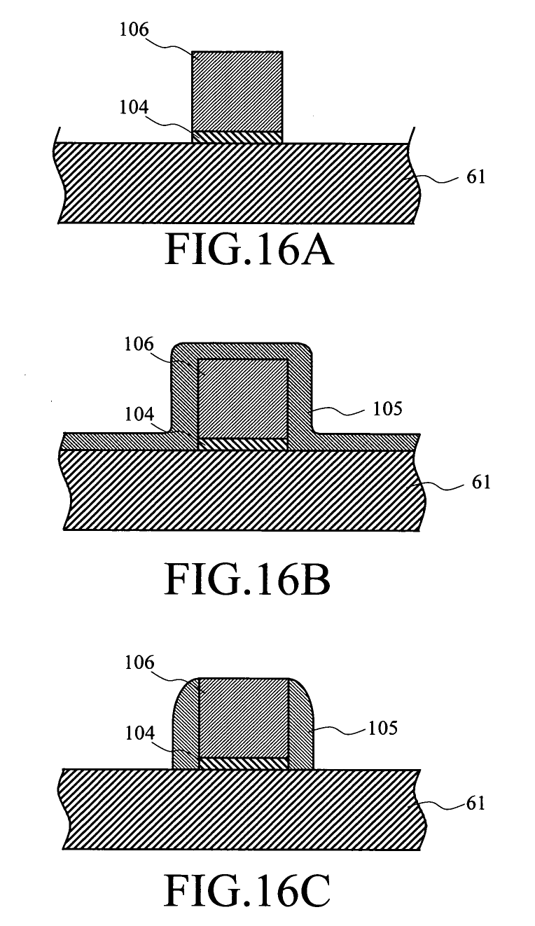

FIGS. 16A through 16C are process cross-sectional views illustrating a method of manufacturing a gate sidewall 105.

First, as shown in FIG. 16A, a gate electrode 106 is formed via a gate isolation film 104 on a substrate 61.

Next, as shown in FIG. 16B, a silicon nitride film 105 is formed thereon. At this time, it can be formed by the method according to the invention as described above with reference to FIGS. 1 to 14.

Next, as shown in FIG. 16C, the silicon nitride film 105 is processed by dry etching to form a sidewall 105. More specifically, as a result of etching in a direction generally normal to the principal surface of the substrate 61 by a highly anisotropic etching method such as RIE (reactive ion etching), silicon nitride film is left only on the side surface of the gate isolation film 104 and gate electrode 106 to be formed as sidewall 105.

Since this sidewall 105 is formed by the method according to the embodiment of the invention, it has good coverage. In other words, when the degree of integration of such a semiconductor integrated circuit increases, the spacing between adjacent gates decreases. As a result, if a conventional deposition method is used, the coverage of silicon nitride film for forming the gate sidewall 105 decreases.

In contrast to this, the silicon nitride film 105 having excellent step coverage can be formed according to the embodiment of the invention by arranging the second catalyzers at a tilted angle to the major surface of the substrate, as explained in FIGS. 1 through 9.

As the result, the highly integrated semiconductor device with highly fine pattern can be manufactured without the variation in the threshold voltage of the transistor.

On the other hand, a silicon dioxide film is generally used as an insulating interlayer film 111. It is necessary to form the source wiring 115S, the gate wiring 115G, and the drain wiring 115D after forming the contact holes in the silicon dioxide film, as illustrated.

However, the depth of the contact hole on the gate electrode 106 of the transistor differs from the depth of the contact hole on the source region 107 and the drain region 108, as shown in FIG. 13. For this reason, the quantity of an over-etching differs when etching for the opening of the contact holes is carried out on the same conditions. Subsequently, a problem such as poor electrical connection of contact occurs. For this reason, the silicon nitride film 110 is provided as an underlay of the silicon dioxide film 111. That is, since the silicon nitride film 110 has high etching selectivity nature to the silicon dioxide film 111, it has a function as an etching stopper in etching process of the silicon dioxide film 111. For this reason, it becomes possible to etch the contact holes having different depths each other simultaneously. A formation of the contact holes is completed by the etching of the silicon nitride film 110 after the etching of the silicon dioxide film 111.

However, when the step coverage on the silicon nitride film 110 is poor, the thickness of the silicon nitride film 110 may vary with distance from an adjacent pattern, as mentioned above. Then, a poor electrical connection may be caused as a result of the variation of the over-etching quantity of the silicon nitride film 110.

According to the embodiment of the invention, the silicon nitride film having excellent step coverage can be formed by appropriately disposing the second catalyzers at a tilted angle to the major surface of the substrate, as explained in FIG. 1 through FIG. 14. As the result, the variation of the over-etching quantity of the silicon nitride film 110 can be prevented. Consequently, problems such as poor electrical connection can be solved.

These points will be described in further detail with reference to the process of manufacturing a semiconductor device.

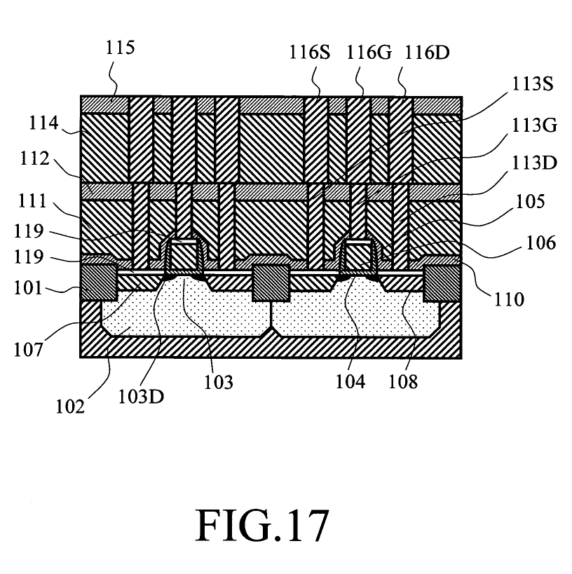

FIG. 17 is a schematic view illustrating the cross-sectional structure of a relevant part of another semiconductor device manufactured according to the invention. More specifically, this figure also shows a relevant part of MOSFET (Metal Oxide Semiconductor Field Effect Transistor) that constitutes a semiconductor integrated circuit. In FIG. 17, elements similar to those described with reference to FIG. 15 are marked with the same numerals and are not described in detail.

In this specific example, the transistor is covered with a first interlayer isolation film 110, a second interlayer isolation film 111 and a third interlayer isolation film 112, through which contact holes penetrate. Source contact 113S, gate contact 113G, and drain contact 113D are formed through the contact holes. Here, the first interlayer isolation film 110 and the third interlayer isolation film 112 can be formed, for example, from silicon nitride. The second interlayer isolation film 111 can be formed, for example, from silicon oxide.

Further thereon, a fourth interlayer isolation film 114 and a fifth interlayer isolation film 115 are formed. In trenches penetrating through them, source wiring 116S, gate wiring 116G, and drain wiring 116D are each embedded. Here, the fourth interlayer isolation film 114 can be formed from silicon oxide. The fifth interlayer isolation film 115 can be formed from silicon nitride.

In manufacturing a semiconductor device as described above, according to the invention, not only the gate sidewall 105, but also the silicon nitride film constituting the gate insulating film 104, the first interlayer isolation film 110, the third interlayer isolation film 112, and the fifth interlayer isolation film 115 can be formed by the method described above with reference to FIGS. 1 to 14.

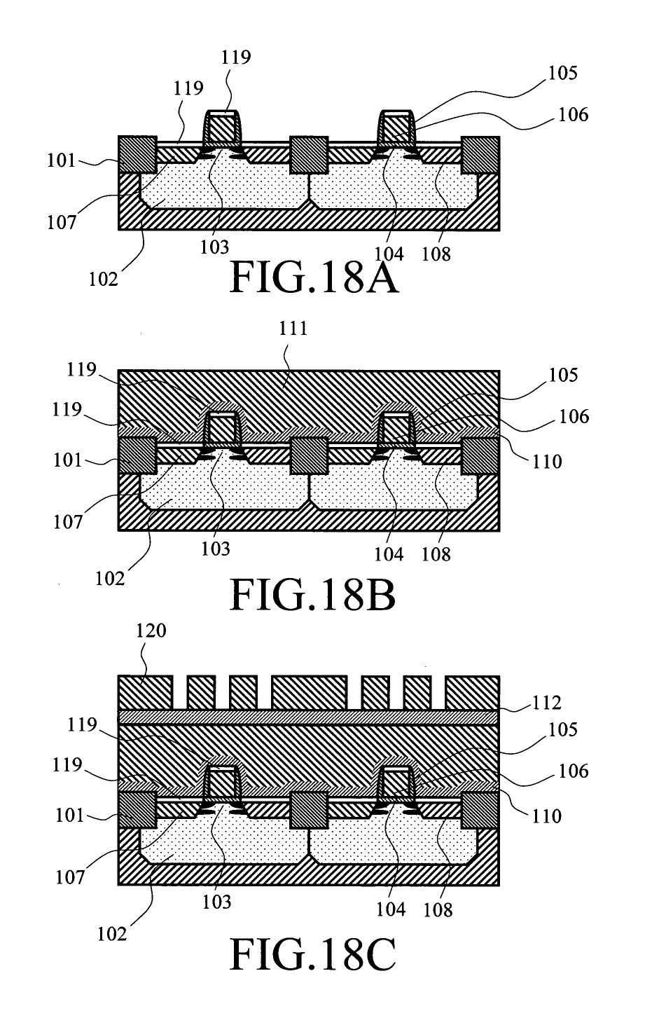

FIGS. 18A to 22B are process cross-sectional views showing a method of manufacturing a semiconductor device of this specific example.

First, as shown in FIG. 18A, the relevant part of MOS transistor is formed. More specifically, on a Si substrate, a component separation region 101, well 102, channel 103, gate isolation film 104, gate electrode 106, and LDD injection sidewall (gate sidewall) 105 are sequentially formed, and a source region 107 and a drain region 108 are formed. Furthermore, nickel (Ni) sputtering and RTP (rapid thermal processing) are sequentially performed to form a silicide layer 119 made of nickel silicide.

Here, in the step of forming the gate isolation film 104, the silicon nitride film can be formed by the method described above with reference to FIGS. 1 to 14. In this respect, the gate isolation film 104 is not limited to a single silicon nitride film. Rather, it can have a stacked structure of a film made of silicon oxide or high-k (high dielectric constant) material and a silicon nitride film. In this case, the method described above with reference to FIGS. 1 to 14 can be carried out with respect to the silicon nitride film.

In addition, also in the step of forming the gate sidewall 105, as described above with reference to FIG. 16, the silicon nitride film can be deposited by the method of the invention.

Next, as shown in FIG. 18B, a first interlayer isolation film 110 and a second interlayer isolation film 111 are formed. Here, for the first interlayer isolation film 110, a silicon nitride film with a thickness of about 50 nm is formed by the method described above with reference to FIGS. 1 to 14. At this time, it is desirable that the temperature during forming the silicon nitride film is kept down at 500 degrees centigrade or less in order to prevent increase of contact resistance of the underlying silicide layer 119 made of nickel silicide. In this respect, according to the invention, a silicon nitride film with good film quality and good coverage can be formed even at a lower temperature of about 450 degrees centigrade, for example.

After the silicon nitride film is thus formed as the first interlayer isolation film 110, a silicon oxide film with a thickness of 600 nm is formed as the second interlayer isolation film 111 by plasma CVD using TEOS (tetra ethoxy silane) gas at 600 degrees centigrade.

Alternatively, the second interlayer isolation film 111 may be made of material with lower dielectric constant. Such material may include silicon oxides having methyl group(s), silicon oxides having hydrogen group(s), and organic polymers. More specifically, the material may include, for example, various silsesquioxane compounds such as porous methyl silsesquioxane (MSQ), polyimide, fluorocarbon, parylene, and benzocyclobutene. The method of forming such materials may include the spin on glass (SOG) method in which a thin film is formed by spin coating and heat treating the solution.

After the second interlayer isolation film 111 is thus formed, as described in FIG. 18C, a silicon nitride film is formed thereon as the third interlayer isolation film 112. Also at this time, according to the method of the invention, a silicon nitride film with a thickness of about 120 nm can be formed at a film formation temperature of about 450 degrees centigrade, for example. By keeping down the film formation temperature, deterioration of nickel silicide constituting the silicide layer 119 can be prevented.

Subsequently, resist is applied and patterned to form a resist pattern 120. The resist pattern 120 is formed, for example, by exposure at 120 nm diameter using an ArF exposure apparatus.

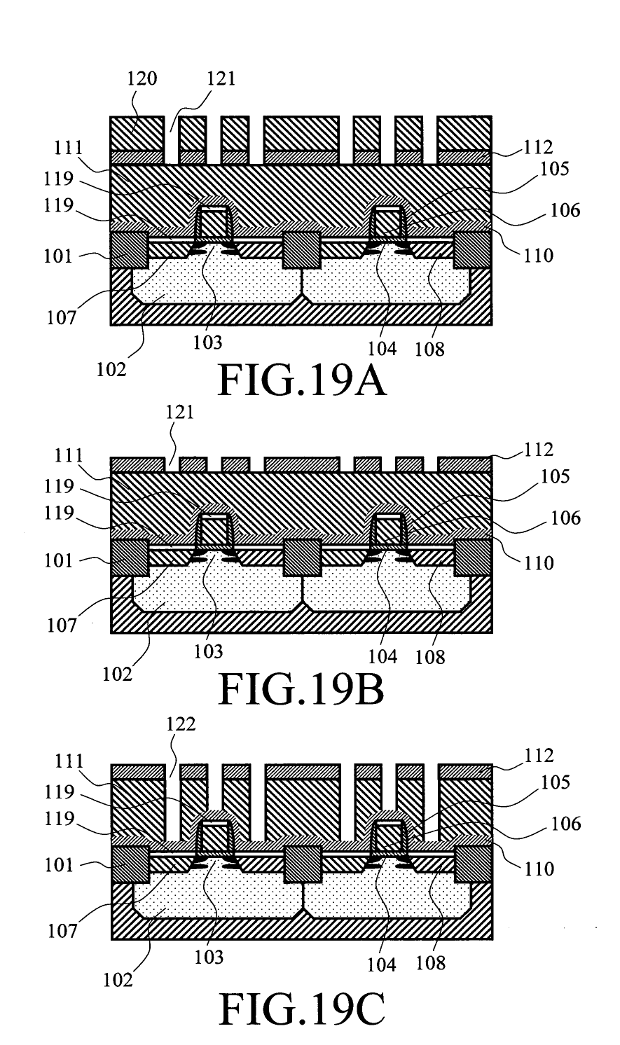

Next, as shown in FIG. 19A, the third interlayer isolation film 112 is etched using the resist pattern 120 as a mask. The etching method may include, for example, a method using ICP (induction coupled plasma) reactive ion etching apparatus. In etching the third interlayer isolation film 112, openings 121 may be formed in the interlayer isolation film 112, for example, by etching it using mixture gas of CH₂F₂ (50 sccm) and O₂ (50 sccm) at 6.7 pascals (Pa).

Next, as shown in FIG. 19B, the resist mask 120 is removed by ashing with oxygen plasma.

Subsequently, as shown in FIG. 19C, contact holes are formed in the second interlayer isolation film 111. In forming contact holes in the second interlayer isolation film 111, reactive ion etching is carried out using mixture gas of C₄F₆ (50 sccm), CO (50 sccm), O₂ (50 sccm), and Ar (200 sccm) at 6.7 pascals. In this manner, the contact holes 122 in the second interlayer isolation film 111 are formed.

At this time, etching can be stably carried out by using the third interlayer isolation film 112 made of silicon nitride film as an etching mask. More specifically, a large etching selection ratio can be easily obtained by causing etching rates to differ between the silicon oxide film constituting the second interlayer isolation film 111 and the silicon nitride film constituting the third interlayer isolation film 112. Consequently, the second interlayer isolation film 111 can be etched in a condition where it is firmly masked by the third interlayer isolation film 112. That is, a desired opening can be stably formed by eliminating problems such as variation of etching opening size due to mask degradation.

On the other hand, since the first interlayer isolation film 110 is formed from the same silicon nitride film as that of the third interlayer isolation film 112, the first interlayer isolation film 110 functions reliably as an etching stopper. That is, problems due to overetching and underetching can also be eliminated.

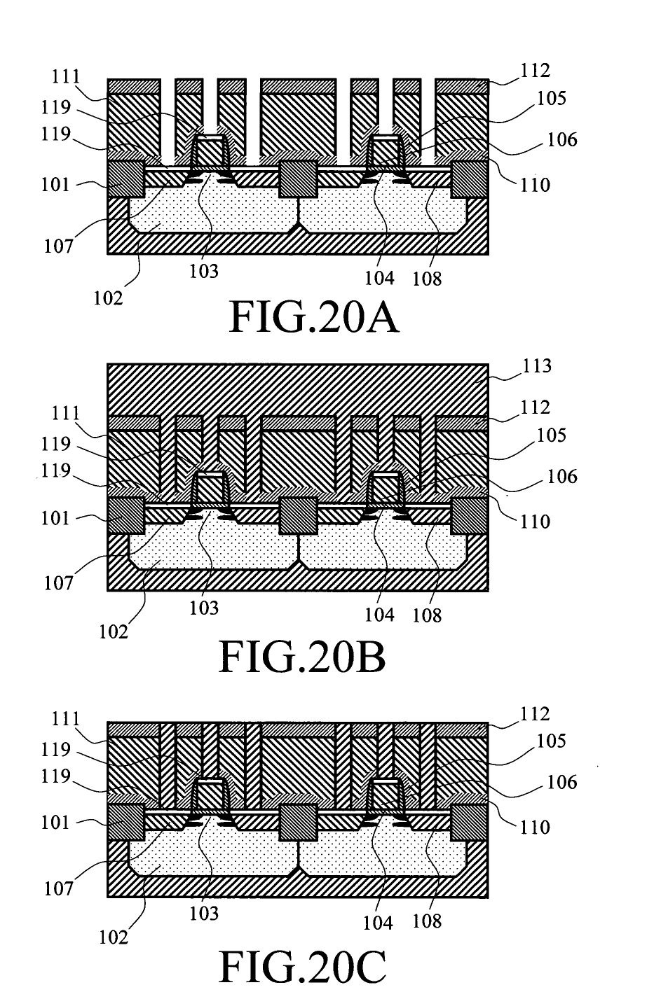

Next, as shown in FIG. 20A, contact holes are formed in the first interlayer isolation film 110. When the first interlayer isolation film 110 is formed from the same kind of materials as that of the third interlayer isolation film 112, the third interlayer isolation film 112 is also etched in this etching step. Consequently, the third interlayer isolation film 112 must be formed with greater thickness than the first interlayer isolation film 110. In terms of the etching condition, etching can be carried out by the reactive ion etching method using mixture gas of CH₂F₂ (50 sccm), O₂ (50 sccm), and Ar (200 sccm) at 6.7 pascals.

Next, as shown in FIG. 20B, contact metal 113 is deposited.

The surface is then polished by chemical mechanical polishing (CMP) for planarization. In this way, a structure in which contact metal is embedded as shown in FIG. 20C can be formed. It should be noted that also at this time, the third interlayer isolation film 112 enables the second interlayer isolation film 111 to be protected against polishing by CMP. More specifically, the second interlayer isolation film 111 can be prevented from being polished and thinned in its film thickness at the time of CMP polishing by providing the third interlayer isolation film 112 made of relatively hard material such as silicon nitride on top of the second interlayer isolation film 111 formed from relatively soft material such as porous silicon oxide. As a result, problems such as increase of interwiring capacitance and current leak can be suppressed.

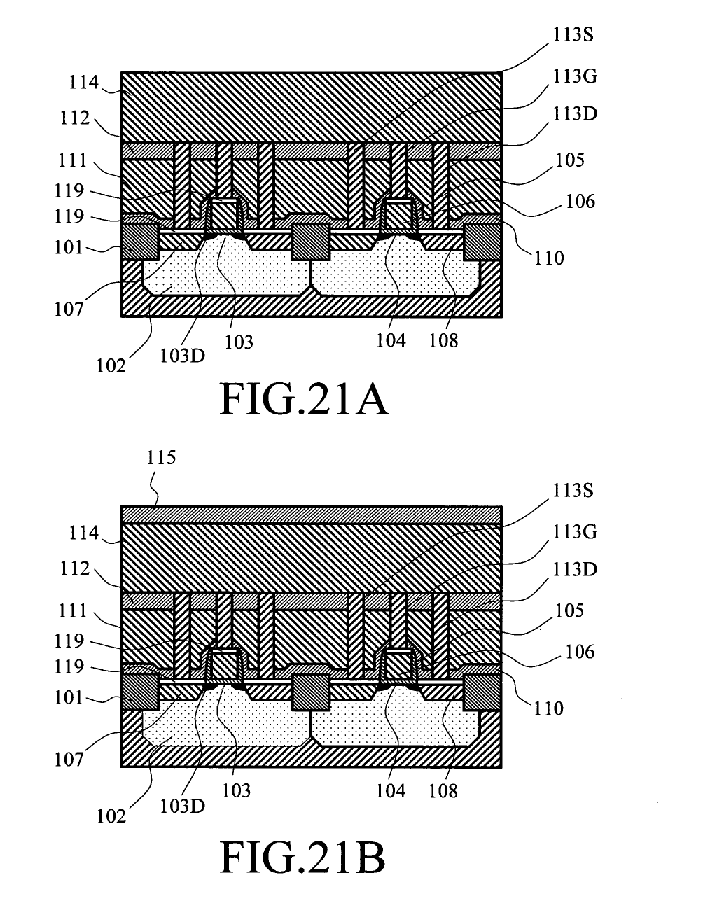

Next, as shown in FIG. 21A, porous silicon oxide is deposited as the fourth interlayer insulating film 114 using raw material such as MSQ. Then, as shown in FIG. 21B, silicon nitride film, for example, is deposited as the fifth interlayer insulating film 115. Also at this time, the method as described above with reference to FIGS. 1 to 14 can be used.

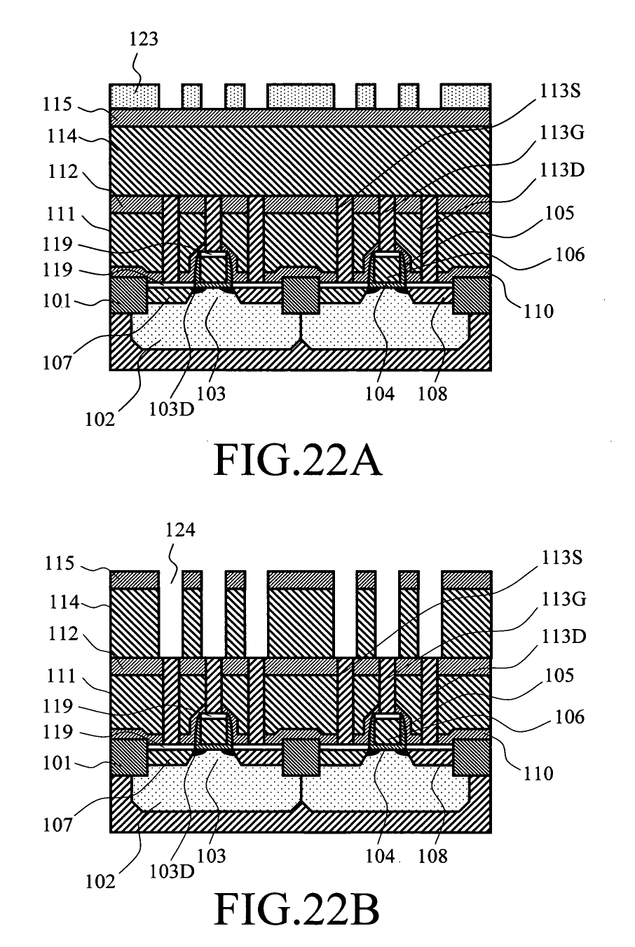

Next, as shown in FIG. 22A, a resist pattern 123 is formed.

Then, as shown in FIG. 22B, trenches 124 are formed by etching the fifth interlayer insulating film 115 and the fourth interlayer insulating film 114, respectively. In etching the fifth interlayer insulating film 115, openings may be formed in the interlayer isolation film 115, for example, by etching it using mixture gas of CH₂F₂ (50 sccm) and O₂ (50 sccm) at 6.7 pascals (Pa). In forming trenches in the fourth interlayer insulating film 114, reactive ion etching may be carried out using mixture gas of C₄F₆ (50 sccm), CO (50 sccm), O₂ (50 sccm), and Ar (200 sccm) at 6.7 pascals. At this time, the fifth interlayer isolation film 115 can be used as a hard mask, and at the same time, the third interlayer isolation film 112 can be used as an etching stopper. More specifically, in etching the fourth interlayer isolation film 114 formed from silicon oxide, the fifth interlayer isolation film 115 formed from silicon nitride can be used as a hard mask, and the third interlayer isolation film 112 also formed from silicon nitride can be used as an etching stopper, to suppress overetching and form the trench with precision.

Subsequently, metal for wiring is deposited, and then smoothing is carried out by CMP polishing. In this way, as shown in FIG. 18, an interlayer wiring structure can be formed in which source wiring 116S, gate wiring 116G, and drain wiring 116D are embedded in the trenches, respectively.

As described above, according to the present embodiment, the silicon nitride film constituting insulating films 105, 110, 112, and 115 acting as a gate sidewall, etching stopper, and hard mask can be formed with good coverage. Consequently, these insulating films can be deposited with good coverage even when the degree of integration of the semiconductor integrated circuit is increased and gate electrodes 106 are closely packed. In addition, the method of forming a silicon nitride film according to the present embodiment can form insulating film at low temperatures, thereby preventing deterioration of the silicide layer 119.

Heretofore, the embodiments of the present invention have been explained, referring to the examples. However, the present invention is not limited to these specific examples.

For example, about the concrete structures, materials, shapes, sizes, of equipments used in the catalytic CVD method may be appropriately selected by those skilled in the art with the known techniques to carry out the invention as taught in the specification and obtain equivalent effects. Furthermore, process conditions such as species of the source gases, species and thickness of the thin film and species, size, temperature and pressure of the substrate may be appropriately selected by those skilled in the art with the known techniques to carry out the invention as taught in the specification and obtain equivalent effects.

Further, also concerning the catalytic CVD equipment and the catalytic CVD method according to the invention, those skilled in the art will be able to carry out the invention appropriately selecting a material or a structure within known techniques.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

1. A catalytic CVD equipment comprising:
a vacuum chamber;
a stage which holds a substrate in the vacuum chamber;
a first catalyzer provided in the vacuum chamber, the first catalyzer having a bar member arranged substantially in parallel to a major surface of the substrate; and
a second catalyzer provided in the vacuum chamber, the second catalyzer having a bar member arranged at a tilted angle to the major surface of the substrate,
wherein a thin film is deposited on the substrate held on the stage by introducing a source gas, by heating the first and the second catalyzer, and by decomposing the gas in the vacuum chamber under a low pressure.

2. The catalytic CVD equipment according to claim 1, wherein the first catalyzer is provided directly above the substrate, and
the second catalyzer is provided partly above the substrate and partly above an outside of the substrate.

3. The catalytic CVD equipment according to claim 1,
wherein at least two second catalyzers are provided, and
the second catalyzers are arranged substantially in a radial fashion from a central axis perpendicular to the substrate.

4. The catalytic CVD equipment according to claim 1, wherein an angle between the bar member of the second catalyzer and the major surface of the substrate is within a range between 30 degrees and 75 degrees.

5. The catalytic CVD equipment according to claim 1, further comprising:
a first power supply which supplies a current to the first catalyzer; and
a second power supply which supplies a current to the second catalyzer.

6. The catalytic CVD equipment according to claim 1, wherein the bar member of the first catalyzer and the bar member of the second catalyzer are parts of a common bar member.

7. A catalytic CVD method to deposit a thin film on a substrate by generating deposition species by decomposing a source gas at a heated catalyzer, wherein at least a part of the catalyzer is arranged at a tilted angle to a major surface of the substrate.

8. The catalytic CVD method according to claim 7, wherein the catalyzer have a first catalyzer having a bar member arranged substantially in parallel to the major surface of the substrate and a second catalyzer having a bar member arranged at a tilted angle to the major surface of the substrate.

9. The catalytic CVD method according to claim 8,
wherein the first catalyzer is provided directly above the substrate, and
the second catalyzer is provided partly above the substrate and partly above an outside of the substrate.

10. The catalytic CVD method according to claim 8,
wherein at least two second catalyzers are provided, and
the second catalyzers are arranged substantially in a radial fashion from a central axis perpendicular to the substrate.

11. The catalytic CVD method according to claim 8, wherein an angle between the bar member of the second catalyzer and the major surface of the substrate is within a range between 30 degrees and 75 degrees.

12. The catalytic CVD method according to claim 8, wherein a first power supply is used to supply a current to the first catalyzer and a second power supply is used to supply a current to the second catalyzer.

13. The catalytic CVD method according to claim 8, wherein the bar member of the first catalyzer and the bar member of the second catalyzer are parts of a common bar member.

14. A method for manufacturing a semiconductor device comprising:
forming a first insulating film on a substrate including a semiconductor layer,
wherein the first insulating film is formed on the substrate by a catalytic CVD method where deposition species are generated by decomposing a source gas at a heated catalyzer, and at least a part of the catalyzer is arranged at a tilted angle to a major surface of the substrate.

15. The method for manufacturing a semiconductor device according to claim 14, wherein the catalyzer have
a first catalyzer having a bar member arranged substantially in parallel to the major surface of the substrate and a second catalyzer having a bar member arranged at a tilted angle to the major surface of the substrate.

16. The method for manufacturing a semiconductor device according to claim 15, wherein the first catalyzer is provided directly above the substrate, and
the second catalyzer is provided partly above the substrate and partly above an outside of the substrate.

17. The method for manufacturing a semiconductor device according to claim 15,
wherein at least two second catalyzers are provided, and
the second catalyzers are arranged substantially in a radial fashion from a central axis perpendicular to the substrate.

18. The method for manufacturing a semiconductor device according to claim 15, wherein an angle between the bar member of the second catalyzer and the major surface of the substrate is within a range between 30 degrees and 75 degrees.

19. The method for manufacturing a semiconductor device according to claim 15, wherein a first power supply is used to supply a current to the first catalyzer and a second power supply is used to supply a current to the second catalyzer.

20. The method for manufacturing a semiconductor device according to claim 15, wherein the bar member of the first catalyzer and the bar member of the second catalyzer are parts of a common bar member.

21. The method for manufacturing a semiconductor device according to claim 15, wherein the semiconductor device has a gate electrode, and the method further comprises:
etching the first insulating film to leave a part of the first insulating film on sidewalls of the gate electrode.

22. The method for manufacturing a semiconductor device according to claim 15, further comprising:
forming a second insulating film made of a material different from a material of the first insulating film after forming the first insulating film; and
forming a hole which reaches the first insulating film through the second insulating film by etching the second insulating film under a condition where a etching rate of the second insulating film is faster than that of the first insulating film.
